(19) United States
(12) Patent Application Publication
(10) Pub. No.: US 2003/0029832 A1
(43) Pub. Date: Feb. 13, 2003

(54) Method for forming large integration and ultra-fine lines on a substrate

(75) Inventor: Ting-Hao Lin, Taoyuan Hsien (TW)

Correspondence Address: Jones, Tullar & Cooper, P.C., Suite 1002, 2001 Jefferson Davis Highway, Arlington, VA, 22202, US

(73) Assignee: Compeq Manufacturing Company Limited

(21) Appl. No.: 09/927,515

(22) Filed: Aug. 13, 2001

(51) Int. Cl. H01L 21/3213

(52) U.S. Cl. 216/46; 216/49; 216/51; 216/67; 216/83; 216/78; 216/100; 216/105; 438/696; 438/739; 438/742; 438/754

(57) ABSTRACT

A method for forming ultra-fine width lines on a substrate avoids occurrence of overetch/underetch defects in the many etching steps, as solder layer or copper film etching steps. With the present method the line shape is able to be achieved close to an ideal shape, so that the quality of the lines is high and the integration of the substrate is also high.

### BACKGROUND OF THE INVENTION

1. Field of the Invention

The present invention relates to a method for forming large integration and ultra-fine width lines on a substrate, and more particularly to a method that is able to avoid overetch and underetch defects appearing in two sidewalls of each line on the substrate.

Furthermore, there are many advantages in a forming line process, such as integrity and stability.

2. Description of Related Art

An etching step of the integrated circuit process for forming lines is important because the line shape is able to affect electronic features of all circuitry.

There are many drawbacks in a conventional etching step, such as commonly-occurring overetch or underetch phenomena, because etching variations are difficult to control in the etching step. Therefore, the lines formed on the substrate effect the electronic features of the integrated circuit.

To overcome the above drawbacks, an available etching step is provided to form the entire line shape, that is, to predetermine a compensation value in the etching step whereby the overetch/underetch portion of the line are respectively added to or further etched. Thus, the line shape formed with the present etching step is able to be close to the expectation and the electronic feature of the integrated circuit is able to be of a normal state.

As the integrated circuit becomes larger, a width of the line of the circuit should be smaller to enable design of the integrated circuit on the same size or even smaller substrate. The fine lines of the circuit still suffer from the overetch and underetch defects found in the present etching step. For example, a multiple layer type IC is suitable for designing of a large integrated circuit in the substrate, wherein the lines of integrated circuit are formed on two opposite surfaces of the substrate. In the present etching step, the substrate should be arranged vertically to enable good execution of the step. If the substrate can not arranged at the correct angle, the line formed on the two opposite surfaces of the substrate are different, that is to say, the line shape on one surface is successful, but the other is not.

To overcome the shortcomings, the present invention provides a method for forming large integration circuit and ultra-fine lines on a substrate to mitigate and obviate the aforementioned problems.

### SUMMARY OF THE INVENTION

The objective of the present invention is to provide an etching step to form ultra-fine lines on a substrate without occurrence of overetch and underetch defects, whereby the high quality of each line is assured.

A further objective of the present invention is to provide a large integration of the circuit on a substrate with a small size.

Other objects, advantages, and novel features of the invention will become more apparent from the following detailed description when taken in conjunction with the accompanying drawings.

### BRIEF DESCRIPTION OF THE DRAWINGS

FIGS. 1A˜1F are schematic cross sectional side views showing the first method forming the ultra-fine lines on a substrate in accordance with the present invention; and

FIGS. 2A˜2F are schematic cross sectional side views showing the second method forming the ultra-fine lines on a substrate in accordance with the present invention.

### DETAILED DESCRIPTION OF THE PREFERRED EMBODIMENT

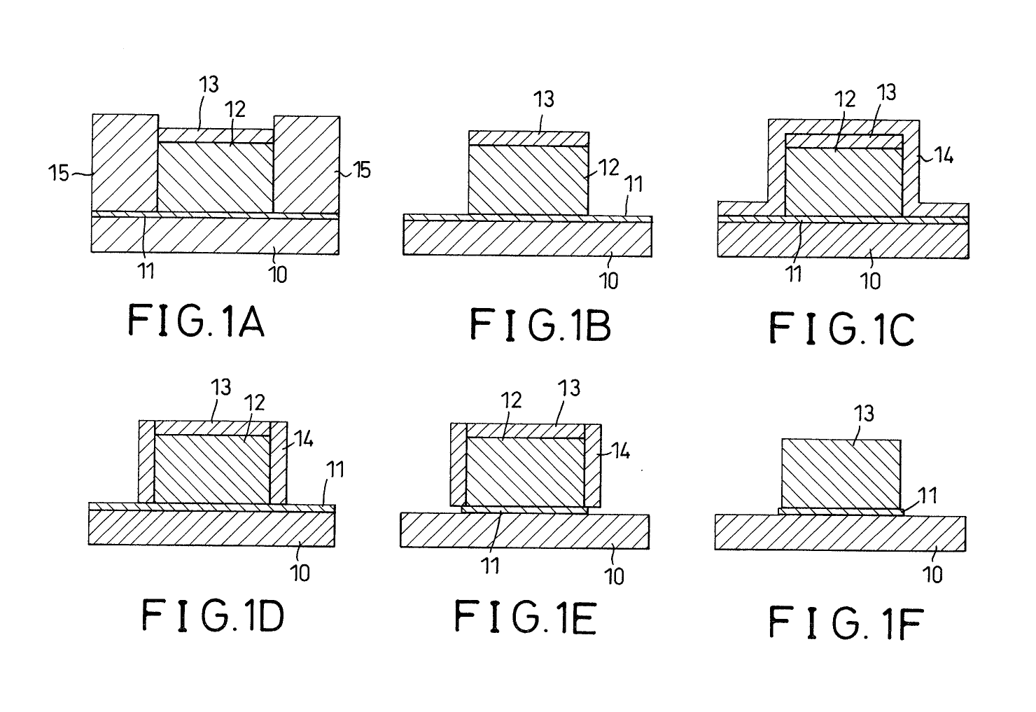

With reference to FIG. 1, a method for forming ultra-fine lines on a substrate (10) is shown, the method comprises the following steps:

pressing a copper film (11) on a surface of the substrate (10), as shown in FIG. 1 A;

forming a pattern transfer upon the copper film (11) for forming copper lines (12) by a photolithography with a photo-resistor (15);

forming a solder layer (13) upon the copper lines (12) for forming an etch-resistance layer on the copper lines (12) ( as shown in FIG. 1 A), and then eliminating the photo-resistor (15) for forming a pattern transfer, as shown in FIG. 1 B;

applying an Electro-Deposited photo-resistor (14) on the copper film (11), sidewalls of the copper line (12) and the surface of the solder layer (13), as shown in FIG. 1 C;

removing the Electro-Deposited photo-resistor (14) covering the copper film (11), as shown in FIG. ID. Thereafter, the Electro-Deposited photo-resistor (14) only covers the sidewalls of the copper lines (12) and top face of the solder layer (13);

removing the copper film (11) that is not covered by the Electro-Deposited photo resistor (14) by a wet etching process, as shown FIG. 1 E, wherein the copper lines (12) are able to avoid being etched because of the Electro-Deposited photo-resistor (14) remaining on the sidewalls of the copper line (12); and

removing the Electro-Deposited photo-resistor (14) covering on the sidewalls of the copper line (12) and the solder layer (13) by a Photolithography which comprises acts such as pattern transfer, exposure and development, as shown in FIG. 1F.

The Electro-Deposited photo-resistor (14) is a sensitizer that has two categories, a positive photoresist and a negative photoresist. In the act of applying photo-resistor, the Electro-Deposited photo-resistor (14) is able to be uniformly attached on the substrate (10) by doping or an electroplate for protecting the copper line (12) from being etched in the next etching step.

In reference to FIGS. 1A and 1B, the copper line (12) shape is uniform, so the Electro-Deposited photo-resistor (14) is able to be consistently doped on the copper line (12) and the sidewalls of the copper line (12).

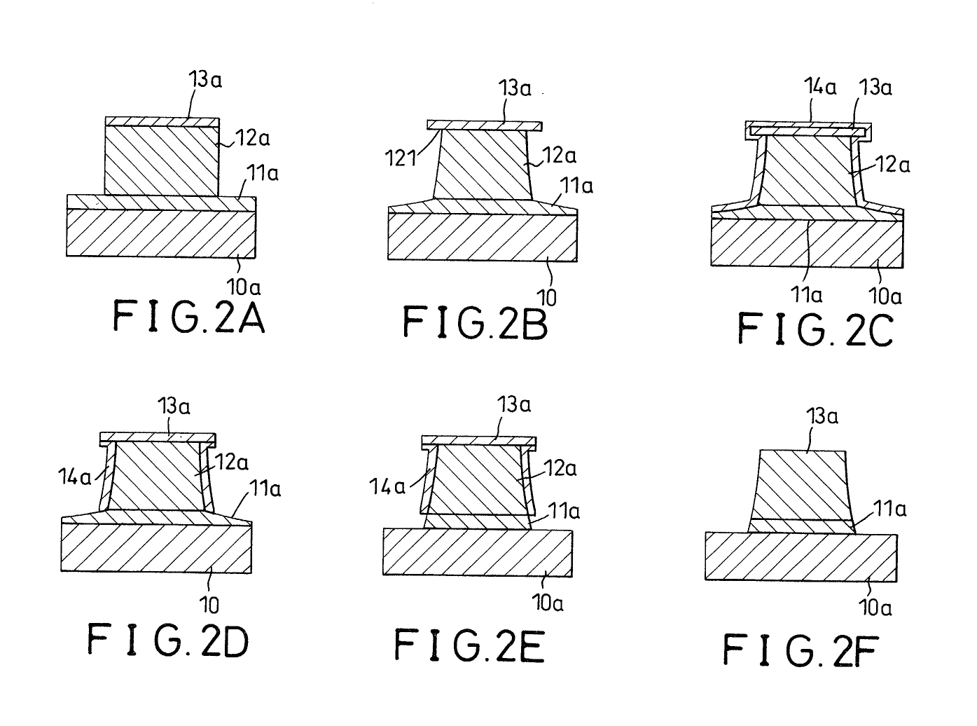

With reference to FIG. 2, another preferred embodiment of the method for forming lines on a substrate (10a) is shown. The method comprises the following steps:

pressing the copper film (11a) on a surface of the substrate (10a), and then forming copper lines (12a) from the film (11a) by a photolithography;

forming a solder layer (13a) on a surface of the copper line (12a), as shown in FIG. 2A;

etching inwardly the copper film (11a) and the copper line (12a) to define a recess (121) between the solder layer (13a) and the sidewalls of the copper line (12a), as shown in FIG. 2B;

applying an Electro-Deposited Photo-resistor (14a) on the copper film (11a) and the copper line (12a) by an electroplating, as shown in FIG. 2C;

removing the portion of the Electro-Deposited Photo-resistor (14a), which is not applied on the sidewalls of the copper line (12a), by exposure and development, as shown in FIG. 2D;

removing by an etching process unnecessary portion of the copper film (11a), which is not covered under the copper line (12a), as shown in FIG. 2E; and

removing the Electro-Deposited Photo-resistor (14a) attached on the sidewalls of copper line (12a) and the solder layer (13a), as shown in FIG. 2F

In reference to FIG. 2B, the sidewalls of the copper line (12a) are slightly etched inward to define the recess (121) between the solder layer (13) and copper line (12a), so the Electro-Deposited Photo-resistor (14) is attached consistently on the copper film (11a) and the copper line (12a) by the electroplating.

In reference to FIG. 2D, in the removing of the Electro-Deposited Photo-resistor step, the recess (121) is defined under the solder layer (13a), so that the portion of the Electro-Deposited Photo-resistor (14a) attached on the sidewalls is able to avoid being exposed to lighting by a ultra-violet light or any lights in the development step of the photolithography. Therefore, the Electro-Deposited Photo-resistor (14a) is still attached on the sidewalls of the copper line (12a) to protect the copper line (12a) without being etched in the removing the copper film and the solder layer steps.

As per the above description, the copper line is able to avoid being etched during the removing the copper film and the solder layer steps, that is conducive to forming the ultra-fine width of the copper line on the substrate. Meanwhile, the method is able to provide not only stability and completeness of line shape but also enables formation of a large integration circuit on the substrate.

Although the present invention has been explained in relation to its preferred embodiment, it is to be understood that many other possible modifications and variations can be made without departing from the spirit and scope of the invention as hereinafter claimed.

What is Claimed is

1. A method for forming integration and ultra-fine lines on a substrate, the method comprising the following steps:
pressing a copper film on a surface of the substrate;
forming copper lines upon the copper film by a pattern transfer;
forming a solder layer upon the copper lines for forming an etch resistance layer on the copper lines;
applying an Electro-Deposited Photo-resistor on the surface of the substrate;
removing the Electro-Deposited Photo-resistor besides a portion of the Electro-Deposited Photo-resistor, which attaching on two sidewalls of the copper line and the solder layer (13);
removing by an etching process an unnecessary portion of the copper film on the substrate; and
removing the Electro-Deposited Photo-resistor formed on the two sidewalls of the copper line and the solder layer.

2. The method as claimed in claim 1, wherein in the applying an Electro-Deposited Photo-resistor step, the Electro-Deposited Photo-resistor is attached on the surface of the substrate by a doping.

3. A method for forming integration and ultra-fine lines on a substrate, the method comprising the following steps:
pressing the copper film on a surface of the substrate, and then forming copper lines from the film;
forming a solder layer on a surface of the copper line;
etching inwardly the copper film and the copper line to define a recess between the solder layer and the sidewalls of the copper line;
applying an Electro-Deposited Photo-resistor on the copper film and the copper line by an electroplating technology;
removing the portion of the Electro-Deposited Photo-resistor, which is not applied on the sidewalls of the copper line, by exposure and development;
removing by an etching process unnecessary portion of the copper film, which is not covered under the copper line; and
removing the Electro-Deposited Photo-resistor attached on the sidewalls of copper line and the solder layer.

4. The method as claimed in claim 3, wherein in the applying an Electro-Deposited Photo-resistor step, the Electro-Deposited Photo-resistor is attached on the surface of the substrate by an electroplating.
